(19) United States
(12) Patent Application Publication
(10) Pub. No.: US 2025/0031314 A1
(43) Pub. Date: Jan. 23, 2025

(54) METHOD FOR PRODUCING AN ELECTRICAL CONNECTION FOR A POWER MODULE OF AN AIRCRAFT

(71) Applicant: SAFRAN, Paris (FR)

(72) Inventors: Rabih KHAZAKA, Moissy-Cramayel (FR); Baptiste Joel Christian FEDI, Moissy-Cramayel (FR)

(21) Appl. No.: 18/714,947

(22) PCT Filed: Dec. 1, 2022
(86) PCT No.: PCT/FR2022/052205

§ 371 Date: May 30, 2024

(30) Foreign Application Priority Data
Dec. 2, 2021 (FR) 2112865

(51) Int. Cl. H05K 1/18; H02K 11/33; H05K 1/02; H05K 3/18

(52) U.S. Cl. CPC H05K 1/189; H02K 11/33; H05K 1/0265; H05K 3/18; H02K 2211/03; H05K 2201/0145; H05K 2201/0154; H05K 2201/0347; H05K 2201/057; H05K 2201/10166; H05K 2201/10272

(57) ABSTRACT

A process carrying out non-planar three-dimensional forming of at least one segment of a flexible printed circuit board including an electrically insulating polymer film, and, on at least one side of the polymer film, a metallization then carrying out electrodeposition in which a conductive layer is deposited on at least the metallization of at least the formed segment.

### TECHNICAL FIELD OF THE INVENTION

The present invention concerns a method for producing an electrical connection for a power module of an aircraft, as well as the power module with an electrical connection thus obtained and an aircraft comprising such a power module.

### TECHNICAL BACKGROUND

A power module comprises power semiconductor components attached to a substrate and connected together by wiring wires and/or conductor tracks extending over an electrically insulating layer of the substrate.

Several busbar solutions are available to interconnect the power module flexibly with busbars, particularly with the two potentials DC+, DC− of a DC voltage.

Firstly, a stack of copper bars can be used, this stack being inserted in an insulating sheath. Such a stack can then be easily deformed in flexion and torsion. It is also less expensive. However, this solution results in a high level of parasitic inductance because of the distance between the two busbars which are intended to be connected to the DC+ and DC− potentials respectively.

It is also possible to fold two laminated busbars together, separated by an insulating layer, these two busbars being intended to be connected to the DC+, DC− potentials. The result is a low parasitic inductance. However, the folding risks weakening the insulating layer and is only possible for small angles.

It is also possible to use hinges for the laminated busbars, which removes the need to fold them. However, it is a complex mechanical part, particularly when it comes to maintaining the electrical insulation through the hinge. As a result, this solution is generally expensive.

It may be desirable to allow the power module to be easily integrated into its environment.

### SUMMARY OF THE INVENTION

A method for producing an electrical connection for a power module of an aircraft is therefore proposed, characterised in that it comprises:
carrying-out a non-planar three-dimensional forming of at least one segment of a flexible printed circuit board comprising an electrically insulating polymer film and, on at least one side of the polymer film, a metallization; then
carrying-out an electrodeposition, during which a conductive layer is deposited on at least the metallization of at least the formed segment.

In this way, it is possible to provide an electrical connection with a complex form that allows a power module to be connected to another electrical device, even when the power module is incorrectly positioned and/or oriented for a direct connection, while still allowing a high current to flow.

The invention may also comprise one or more of the following optional characteristics, in any technically possible combination.

Optionally, the insulating polymer film comprises at least one of: PI polymide, PET polyethylene terephthalate, PE polyester.

Also optionally, the insulating polymer film has a thickness of at most 100 μm, for example between 18 μm and 100 μm.

Also optionally, each metallization also comprises copper.

Also optionally, each metallization has a thickness of at most 70 μm.

Also optionally, the printed circuit board preferably comprises a metallization on both sides of the polymer film, superimposed on each other. These two metallizations can therefore be connected to the two DC+ and DC− potentials of a DC voltage. The power module can therefore be connected to this DC voltage with a reduced parasitic inductance.

Also optionally, the metallization or the metallizations form electrical tracks including an electrical track referred to as power electrical track and an electrical track referred to as control electrical track, and the method further comprises: —attaching a power semiconductor component to the printed circuit board, so that this power semiconductor component is electrically connected to the power track; —connecting the power semiconductor component to the control track; and —attaching a control electronics to the printed circuit board, so that this control electronics is electrically connected to the control track to control the power semiconductor component. Using the same printed circuit board for the semiconductor component and the control electronics simplifies the integration, as well as the interconnection, which is made easy thanks to the control track provided on the printed circuit board.

Also optionally, the power track extends over the formed segment of the printed circuit board, and the method further comprises an encapsulation of at least the power semiconductor component, leaving at least a segment of the printed circuit board exposed, over which the power track extends. In the current prior art, the power module is often connected using connectors soldered to the substrate, which are in turn attached to a busbar. In addition to their high inductance, these connectors have a limited reliability due to the vibrations and the thermomechanical cycles, which weaken the solder. Thanks to this optional characteristic of the invention, the segments of the printed circuit board protruding from the encapsulation can be used as connections which do not have the disadvantages of the soldered connectors of the prior art.

Also optionally, the method also comprises:
prior to the electrodeposition, attaching at least one preform to the formed segment of the printed circuit board, this preform comprising a polymer body and a metallization in contact with the metallization of the printed circuit board; and
during the electrodeposition, depositing a conductive layer on the metallization of each preform. In this way, the preform can be used as a connector with the desired form.

Also optionally, each preform also comprises a tongue with a hole. In this way, the connection can be made by means of a screw or equivalent, through the hole.

Also optionally, the method also comprises dissolving, for example thermally or chemically, the polymer body of each preform. This preform is generally only used as a support for the metallization. Once the latter has been achieved, the preform is no longer useful and its dissolution allows to reduce the mass of the power module and avoids any problems resulting from the degradation of the preform over time.

Also optionally, the power module implements at least one switching arm of an inverter for an electric motor of an aircraft.

Also proposed is an electrical module for an aircraft, at least one electrical connection of which is obtained by a method according to the invention.

An aircraft comprising an electrical module according to the invention is also proposed.

### BRIEF DESCRIPTION OF THE FIGURES

The invention will be better understood with the aid of the following description, given only by way of example and made with reference to the attached drawings in which:

FIG. 1 is an electronic circuit of an electrical device that can be made at least in part according to the invention,

FIG. 2 is a planar view of a flexible printed circuit board that can be used in the invention to make a switching arm, the top image being a top view of the flexible printed circuit board and the bottom image being a bottom view of the flexible printed circuit board,

FIG. 3 is a block diagram of a method according to the invention for producing a power module,

FIG. 4 is a top view of the formed flexible printed circuit board,

FIG. 5 is a top view of the flexible printed circuit board after an electrodeposition,

FIG. 6 is a top view of the flexible printed circuit board after attaching components and a production of electrical connections,

FIG. 7 is a top view of a flexible printed circuit board that can be used in the invention to produce several switching arms,

FIG. 8 is a block diagram of a method according to the invention for producing an electrical connection,

FIG. 9 is a three-dimensional view of a formed printed circuit board,

FIG. 10 is a three-dimensional view of the formed printed circuit board shown in FIG. 9, with an added preform,

FIG. 11 is a three-dimensional view of the formed printed circuit board of FIG. 10, after carrying-out an electrodeposition, and

FIG. 12 is a cross-sectional view of the printed circuit board in FIG. 11.

### DETAILED DESCRIPTION OF THE INVENTION

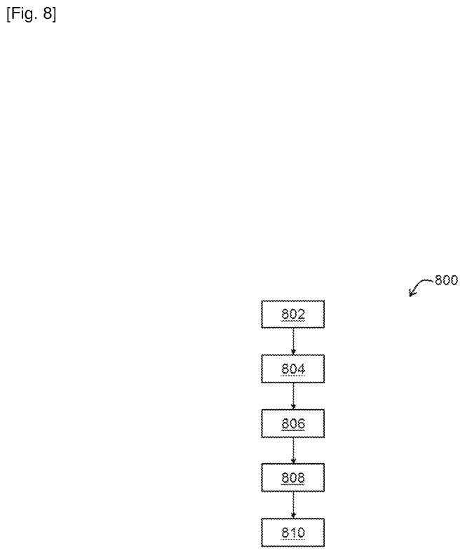

With reference to FIG. 8, an example of a method 800 according to the invention, for producing an electrical connection, will now be described.

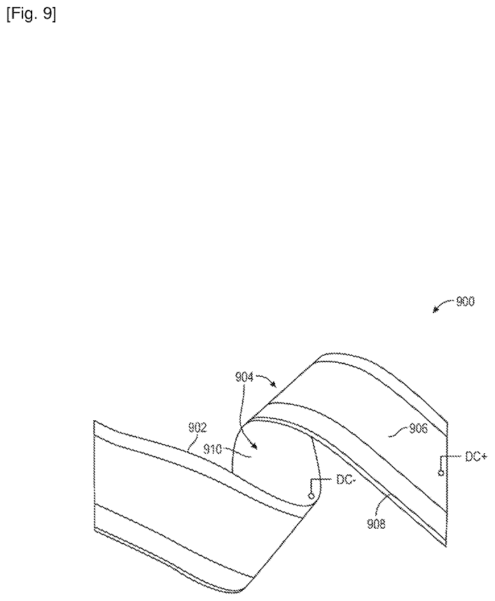

In a step 802, illustrated in FIG. 9, a printed circuit board 900 is formed, in particular folded or twisted as required, into a non-planar three-dimensional configuration.

The printed circuit board 900 is flexible and comprises an electrically insulating polymer film 902 and, on at least one side of the polymer film 902, an electrically conductive metallization 904. In the example shown, two metallizations 904 are provided, one on each side of the polymer film 902. The printed circuit board 900 is in the form of a strip, for example.

The polymer film 902 preferably has a thickness of at most 100 μm, for example between 18 μm and 100 μm. Each metallization 904 preferably has a thickness of at most 70 μm. This means that the printed circuit board 900 can be very flexible.

The polymer film 902 comprises, for example, at least one of: PI polymide, PET polyethylene, terephthalate, and PE polyester. Each metallization 904 may comprise copper, for example made of copper.

Each metallization 904 can form one or more electrical tracks. These electrical tracks include at least one electrical track referred to as power electrical track and, for example, an electrical track referred to as control electrical track. In the example shown, the metallization 904 provided on one side (for example, above) forms a power track 906, as well as at least one control track 908. The metallization 904 provided on the other side (for example, underneath) forms a second power track 910. Preferably, these tracks 906, 910 are intended to be connected respectively to a positive potential DC+ and a negative potential DC− of a DC voltage. The superimposition of these two tracks 906, 910 on either side of the polymer film 902 allows to reduce the parasitic inductance of the electrical connection. For example, the tracks extend along the strip formed by the printed circuit board 900. The control track 908 has a much smaller width (for example at least ten times smaller) than the power tracks 906, 910.

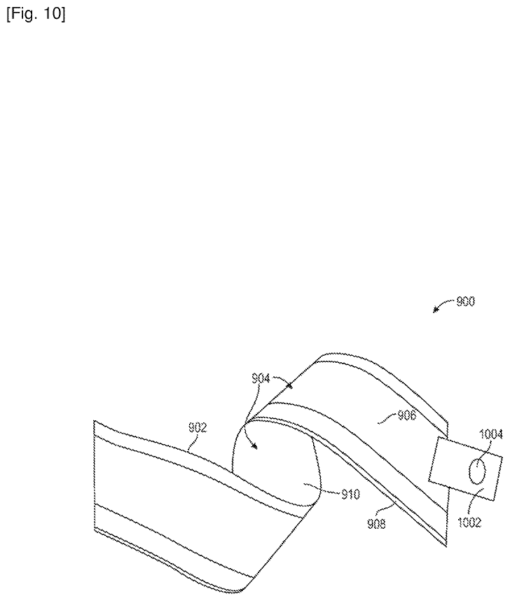

In a step 804, illustrated in FIG. 10, at least one preform 1002 is attached to the printed circuit board 900, for example at one end of the strip formed by the printed circuit board 900. The preform 1002 comprises, for example, a polymer body and a metallization on this polymer body, in contact with an electrical track. In the example described, the preform 1002 is attached so as to be in electrical contact with the electrical power track 906.

Preferably, the preform 1002 comprises a tongue pierced with a hole 1004 to allow its attachment, for example to a busbar, by means of a screw or equivalent.

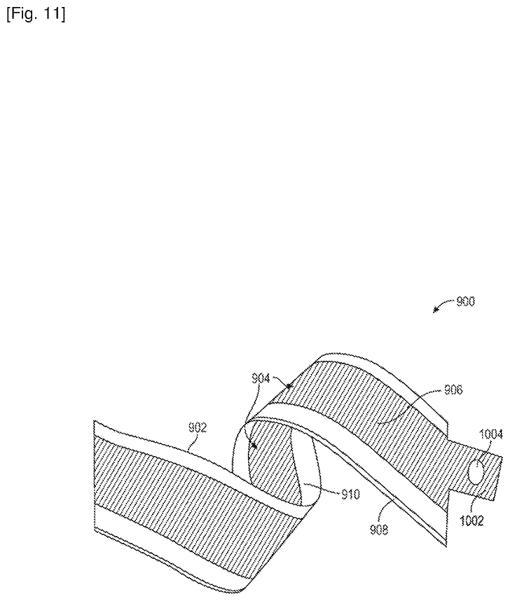

In a step 806, illustrated in FIG. 11, an electrodeposition is carried out. During this electrodeposition, a conductive layer is deposited on each power track 906, 910 to increase its thickness, but preferably not on the control track 908. A conductive layer can also be deposited on the metallization of the preform 1002.

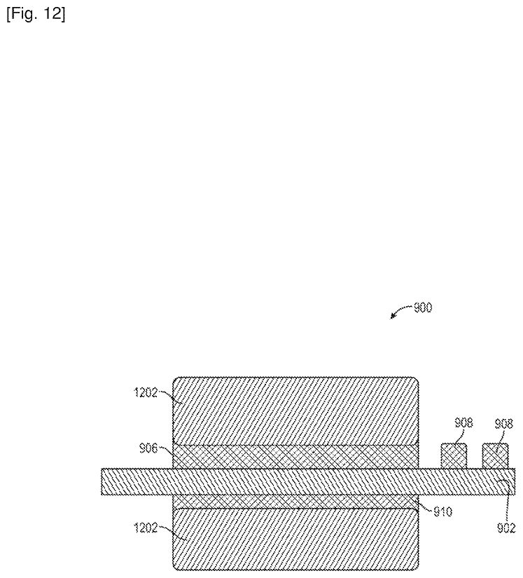

The result of the deposition can be seen in FIG. 12, where the reference 1202 refers to the conductive layers deposited.

During the electrodeposition, the printed circuit board 900 is held in the form defined in step 802, for example by supports provided at the edges of the printed circuit board 900. Alternatively, the printed circuit board 900 can held its form on its own, if its flexibility does not cause it to deform under its own weight and that of the electrodeposition.

The electrodeposition can be carried out in two stages, once on one side and then on the other. This means that the printed circuit board 900 can be held in form by supports on the side where the electrodeposition is not carried out.

The deposited conductive layer 1202 comprises, for example, at least one of: copper, silver, nickel, nickel alloy, copper alloy, such as CuSn, CuZn.

Preferably, in order to allow a good dissipation of the heat generated by the passage of the current in the power tracks 906, 910, the deposited conductive layer has a thickness of more than 500 μm, which may be as much as a few millimetres.

Once deposited, the conductive layer provides a sufficient rigidity, for example, to hold the printed circuit board 900 in form.

In a step 808, the polymer body of each preform 402 can be dissolved, for example by thermal or chemical dissolution.

In step 810, an electrically insulating layer, for example a polymer layer, can be deposited on the surface of the conductor tracks, for example by a method of impregnation, spray coating or physical vapour deposition.

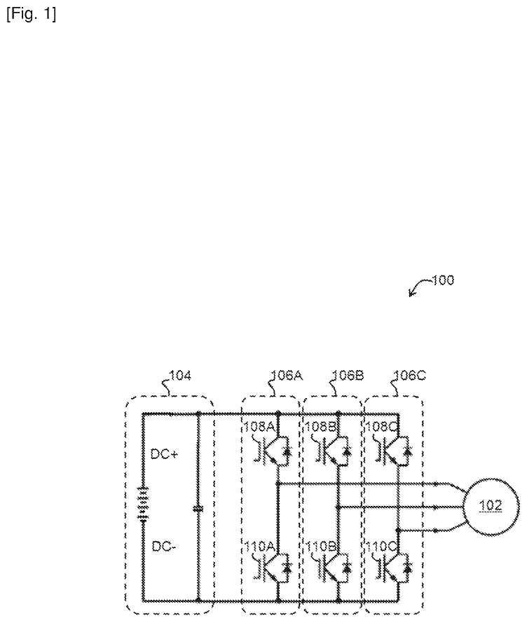

With reference to FIG. 1, an example of an electrical device 100 that can be made at least in part according to the invention will now be described.

In the illustrated example, the electrical device 100 is an inverter, in particular a three-phase inverter, designed to supply an electric motor 102 from a DC voltage source 104 designed to supply a DC voltage having a positive potential DC+ and a negative potential DC−. The inverter 100 comprises several switching arms 106A-C. Each switching arm 106A-C comprises a high-side switch 108A-C and a low-side switch 110A-C connected to each other at a midpoint connected to a respective stator phase of the electric motor 102. The high-side 108A-C and low-side 110A-C switches are also connected to a positive and negative terminal respectively of the DC voltage source 104. By switching the high-side 108A-C and the low-side 110A-C switches, in particular in opposition for each switching arm 106A-C, it is possible to generate phase AC voltages from the DC voltage at the midpoints.

The switches 108A-C, 110A-C comprise, for example, an IGBT (“insulated gate bipolar transistor”), a HEMT (“high electron mobility transistor”), a MOSFET (“Metal Oxide Semiconductor Field Effect Transistor”) or other, with or without a freewheeling diode in parallel.

For example, each switching arm is implemented in a respective power module. Alternatively, all the switching arms can be implemented in a single power module.

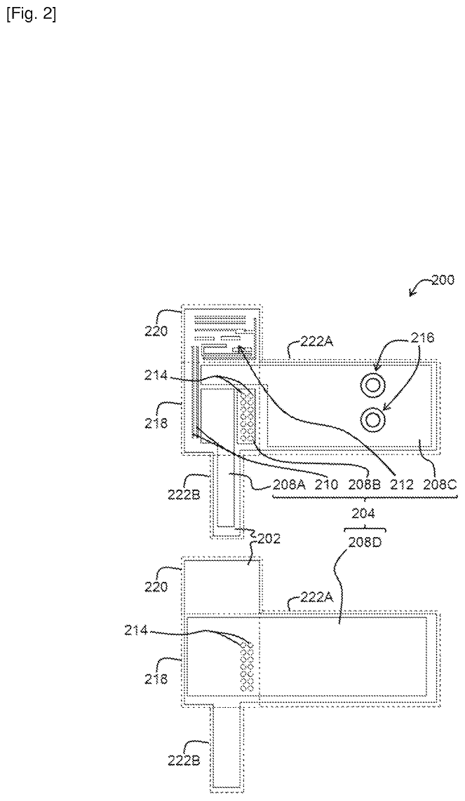

With reference to FIG. 2, an example of a printed circuit board 200 that can be used in the invention will now be described.

The printed circuit board 200 is flexible and comprises an electrically insulating polymer film 202 and, on at least one side of the polymer film 202, an electrically conductive metallization 204. In the example shown, two metallizations 204 are provided, one on each side of the polymer film 202.

The polymer film 202 preferably has a thickness of at most 100 μm, for example between 18 μm and 100 μm. Each metallization is preferably at most 70 μm thick. In this way, the printed circuit board 200 can be flexible.

The polymer film 202 comprises, for example, at least one of: PI polymide, PET polyethylene, terephthalate, and PE polyester. Each metallization 204 may comprise copper, for example made of copper.

Each metallization 204 can form one or more electrical tracks. In particular, these electrical tracks include at least one electrical track, referred to as the power electrical track, and at least one electrical track, referred to as the control electrical track. In the example shown, the metallization 204 on one side (e.g. above) forms three power tracks 208A-C, two control tracks 210 and other tracks 212. The metallization 204 provided on the other side (for example, underneath) forms a power track 208D.

The printed circuit board 200 may comprise at least one via 214 connecting two of the electrical tracks extending respectively on both sides of the polymer film 202, such as the power tracks 208B and 208D in the example shown.

The printed circuit board 200 may also comprise, on one side, preferably in an electrical track on that side, an opening 216 revealing part of an electrical track on the other side and, around this part, the polymer film 202. In the illustrated example, each opening 216 is provided at the top, in the power track 208C, to reveal the power track 208D extending beneath polymer film 202.

For example, the printed circuit board 200 has a segment 218, referred to as power segment, for receiving the power semiconductor component. For example, the printed circuit board 200 also has a segment 220, referred to as control segment, for receiving the control electronics. The printed circuit board 200 also has, for example, at least one segment, referred to as power connection segment, over which at least part of one of the power tracks 208A-D extends. Two power connection segments 222A-B are provided in the example shown.

It will be appreciated that the control tracks 210 extend over the control segment 220 and over the power segment 218. In addition, the power connection track 208A extends over the power segment 218 and over the power connection segment 222B. Each of the power connection tracks 208C, 208D extends over the power segment 218 and over the power connection segment 222A.

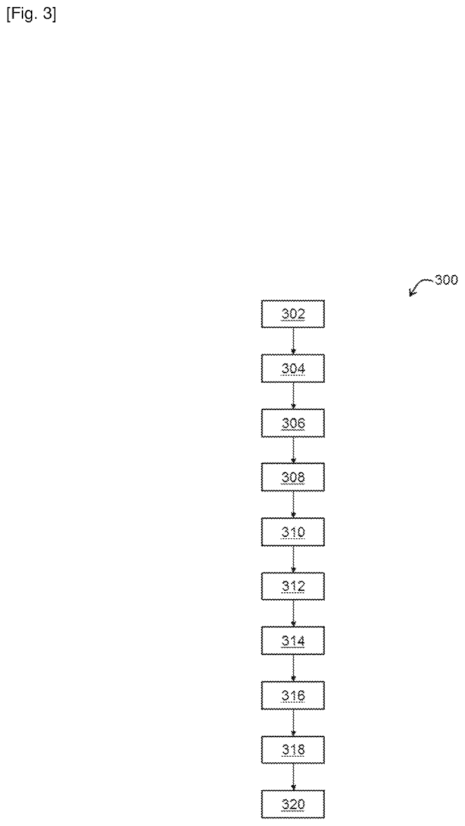

With reference to FIG. 3, an example of method 300 according to the invention for producing and connecting a power module, for example a power module of the inverter 100 of FIG. 1, will now be described.

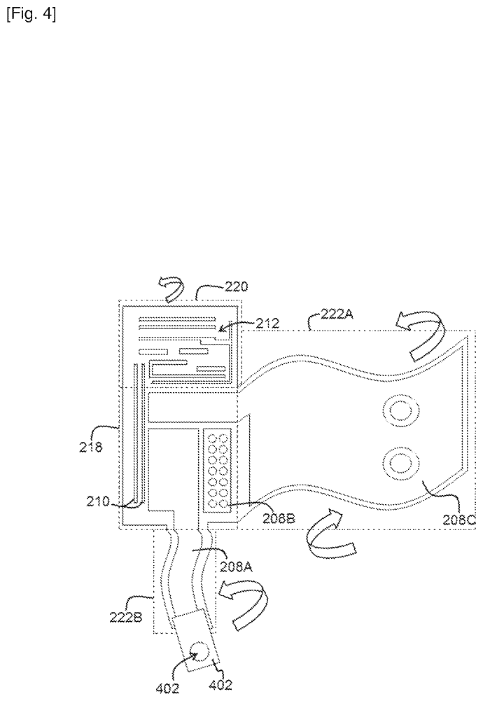

In a step 302, illustrated in FIG. 4, the printed circuit board 200 is formed. Preferably, the power 218 and control 220 segments are each kept planar. The power connection segments 222A-B can be folded or twisted, as required, into a non-planar three-dimensional configuration.

In a step 304, also illustrated in FIG. 4, at least one preform 402 is attached to the printed circuit board 200, in particular to one of the power connection segments 222A-B. The preform 402 comprises, for example, a polymer body and a metallization on this polymer body, in contact with an electrical track. In the example described, the preform 402 is attached to the power connection segment 222B so as to be in electrical contact with the power connection electrical track 222B.

Preferably, the preform 402 comprises a tongue pierced with a hole 404 to allow it to be attached, for example to a busbar, by means of a screw or equivalent.

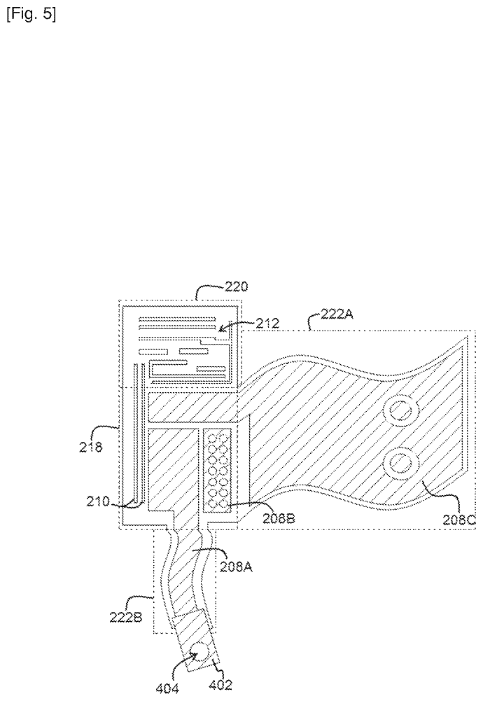

In a step 306, illustrated in FIG. 5, an electrodeposition is carried out. During this electrodeposition, a conductive layer is deposited on each power track 208A-D to increase its thickness, but preferably not on the control tracks 210 or on the other tracks 212. A conductive layer can also be deposited on the metallization of each preform 402.

During the electrodeposition, the printed circuit board 200 is held in the form defined in step 302, for example by supports provided at the edges of the printed circuit board 200. Alternatively, the printed circuit board 200 can held its form on its own, if its flexibility does not cause it to deform under its own weight and that of the electrodeposition.

The electrodeposition can be carried out in two stages, once on one side and then on the other. This allows the printed circuit board 200 to be held in form by supports on the side where the electrodeposition is not carried out.

The deposited conductive layer comprises, for example, at least one of: copper, silver, nickel, nickel alloy, copper alloy, such as CuSn, CuZn.

Preferably, to ensure a good dissipation of the heat generated by the power components, the deposited conductive layer is thicker than 500 μm, up to a few millimetres.

Once deposited, the conductive layer provides a sufficient rigidity, for example, to hold the power connection segments 222A-B in form.

In a step 308, the polymer body of each preform 402 can be dissolved, for example by thermal or chemical dissolution. This leaves the pierced tongue, which can be used for an electrical connection.

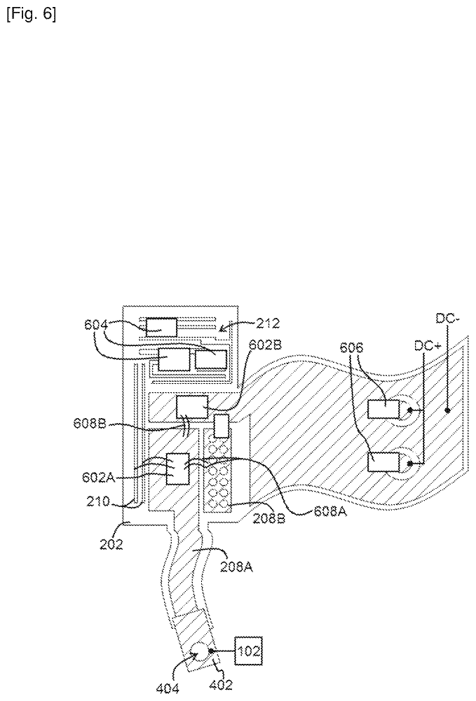

In a step 310, illustrated in FIG. 6, at least one power semiconductor component is attached to the printed circuit board 302, so that this semiconductor component is electrically connected to one of the power tracks. In the example described, two power semiconductor components 602A-B are attached to the conductive layer deposited on the power tracks 208A, 208C respectively, in the power segment 218. The power semiconductor components 602A-B are in particular the high-side 108A-C and low-side 110A-C switches of a single switching arm of the inverter 100 of FIG. 1.

Also during step 306, electrical components 604 forming a control electronics are attached to the printed circuit board 302 so as to be electrically connected to each other by the tracks 212, as well as to the control tracks 210. The control electronics comprises, for example, a driver for the power semiconductor components 602A, 602B.

In addition, during step 310, decoupling capacitors 606 may be connected to the printed circuit board 200, between electrical tracks on the latter, for example, between the electrical tracks 208C and 208D in the example shown.

In step 312, electrical connections are made, for example using wires or ribbons. These electrical connections comprise in particular electrical connections connecting each power semiconductor component 602A, 602B to another power track. In the example shown, the power semiconductor component 602A is connected to the power track 208B by an electrical connection 608A, while the power semiconductor component 602B is connected to the power track 208A by an electrical connection 608B. In addition, the electrical connections electrically connect each power semiconductor component 602A, 602B to a respective one of the control tracks. The latter connect the components 604 of the control electronics to the power semiconductor components 602A, 602B to control them. FIG. 6 illustrates the electrical connections 608C that connect the power semiconductor component 602A to the control tracks 210. Similar connections could connect the power semiconductor component 602B to other control tracks.

In a step 314, at least one of the power semiconductor components 602A, 602B and possibly all or some of the control electronics components 604 are encapsulated in an electrically insulating material (for example, by a dam and fill method or by a glob-top method), surrounded or not by a housing. This encapsulation leaves at least the power connection segments 222A, 222B visible.

In step 316, an electrically insulating layer, for example a polymer layer, can be deposited on the surface of the conductor tracks, for example by a method of impregnation, spray coating or physical vapour deposition.

During a step 318, the printed circuit board 200 can be folded, in particular at a joint between the power segment 218 and the control segment 220, so that the latter forms a non-planar angle with respect to the power segment. This is particularly advantageous in the case of an electrical machine with a cylindrical casing having external planar faces at an angle to each other. In this way, the power segment 218 can be easily pressed to one of the planar faces and the control segment 220 to another of the planar faces, for example adjacent to the first.

In a step 320, the power tracks 208A, 208C, 208D of the power segments 222A, 222B left exposed are electrically connected, for example to busbars. In particular, in the example shown in FIG. 1, the power tracks 208C, 208D extending on either side of the polymer film 202 are respectively connected to the DC+, DC− potentials, while the power track 208A, forming the midpoint of the switching arm, is connected to the respective stator phase of the electric motor 102, for example by means of the pierced tongue.

In the power module obtained, it is preferably provided that two tracks extending on either side of the polymer film are arranged so that the currents flowing through them do so in opposite directions. This is the case, for example, for the power tracks 208C and 208D. This further reduces the parasitic inductance.

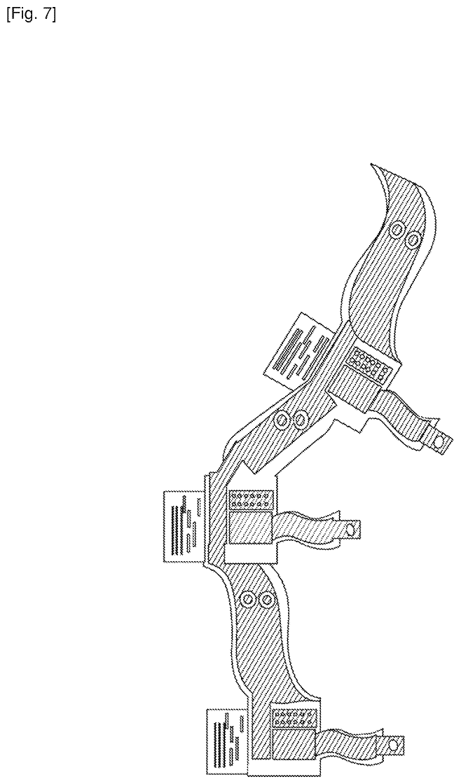

FIG. 7 illustrates a case where the assembly of the switching arms are made from a single flexible printed circuit board.

In conclusion, it is clear that a method such as the one described above allows to obtain a low parasitic inductance between the power tracks. It also allows a very high degree of flexibility in the form of the connections, which makes it easy to integrate (low compactness). It also allows to limit the mechanical stress caused by vibration on the connectors screwed to the module. It is also simple and suitable for mass production at reasonable cost. It also allows the thickness of the metal to be controlled at selective points by choosing where to carry out the electrodeposition. This allows to compensate for the thickness of the semiconductor components, for example, so that they are at the same height, allowing them to be connected to each other by a rigid connection such as a metal frame. It also means that a single type of flexible substrate, the flexible printed circuit board, can be used to make the circuits of the modules, the connectors and the control circuit, and therefore all the connections in a single technology.

It will be further noted that the invention is not limited to the embodiments described above. In fact, it will appear to the person skilled in the art that various modifications can be made to the above-described embodiments, in the light of the teaching just disclosed.

In particular, the method steps 300 described above can be carried out in any technically possible order.

In the foregoing detailed presentation of the invention, the terms used should not be interpreted as limiting the invention to the embodiments exposed in the present description, but should be interpreted to include all equivalents the anticipation of which is within the reach of the person skilled in the art by applying his general knowledge to the implementation of the teaching just disclosed.

1. A method for producing an electrical connection for a power module of an aircraft, wherein the method comprises:
carrying-out a non-planar three-dimensional forming of at least one segment of a flexible printed circuit board comprising an electrically insulating polymer film and, on at least one side of the polymer film, a metallization; then
carrying-out an electrodeposition during which a conductive layer is deposited on at least the metallization of at least the formed segment.

2. The method according to claim 1, wherein the insulating polymer film comprises at least one of: PI polymide, PET polyethylene terephthalate, PE polyester.

3. The method according to claim 1, wherein the insulating polymer film has a thickness of at most 100 μm, for example between 18 μm and 100 μm.

4. The method according to claim 1, wherein each metallization comprises copper.

5. The method according to claim 1, wherein each metallization has a thickness of at most 70 μm.

6. The method according to claim 1, wherein the printed circuit board comprises a metallization on both sides of the polymer film, superimposed on each other.

7. The method according to claim 1, wherein the metallization or the metallizations form electrical tracks including an electrical track referred to as power electrical track and an electrical track referred to as control electrical track, and further comprising:
attaching a power semiconductor component to the printed circuit board, so that this power semiconductor component is electrically connected to the power track;
connecting the power semiconductor component to the control track; and
attaching a control electronics to the printed circuit board, so that this control electronics is electrically connected to the control track to control the power semiconductor component.

8. The method according to claim 7, wherein the power track extends over the formed segment of the printed circuit board, and further comprising an encapsulation of at least the power semiconductor component, leaving at least this formed segment of the printed circuit board exposed.

9. The method according to claim 1, further comprising:
prior to the electrodeposition-, attaching at least one preform to the formed segment of the printed circuit board, this preform comprising a polymer body and a metallization in contact with the metallization of the printed circuit board; and
during the electrodeposition, depositing a conductive layer on the metallization of each preform.

10. The method according to claim 9, wherein each preform comprises a tongue with hole.

11. The method according to claim 9, further comprising dissolving, for example thermally or chemically, the polymer body of each preform.

12. The method according to claim 1, for producing an electrical connection for a switching arm of an inverter for an electric motor of an aircraft.

13. A power module for an aircraft, at least one electrical connection of which is obtained by a method according to claim 1.

14. An aircraft comprising a power module according to claim 13.
